(19) United States
(12) Patent Application Publication
(10) Pub. No.: US 2025/0251468 A1
(43) Pub. Date: Aug. 7, 2025

(54) POWER TOPOLOGY ESTIMATION APPARATUS, POWER TOPOLOGY ESTIMATION METHOD AND PROGRAM

(71) Applicant: NIPPON TELEGRAPH AND TELEPHONE CORPORATION, Tokyo (JP)

(72) Inventors: Ryo SATO, Tokyo (JP); Kosuke SAKATA, Tokyo (JP); Tomonari FUJIMOTO, Tokyo (JP); Motomu NAKAJIMA, Tokyo (JP); Yuji SHINOZAKI, Tokyo (JP); Norihiko OBAYASHI, Tokyo (JP); Yoshikazu NAKAMURA, Tokyo (JP)

(21) Appl. No.: 18/835,160

(22) PCT Filed: Feb. 7, 2022
(86) PCT No.: PCT/JP2022/004750

§ 371 Date: Aug. 1, 2024

(51) Int. Cl. G01R 31/58; G01R 19/25; G01R 31/40

(52) U.S. Cl. CPC G01R 31/58; G01R 19/2513; G01R 31/40

(57) ABSTRACT

A power topology estimation apparatus according to an embodiment estimates connection relationships between one or more power sources and one or more load devices. The power topology estimation apparatus includes: a reception unit configured to receive, for each of the one or more power sources, a measured current value obtained by measuring a value of a current from the power source; a current estimation unit configured to calculate, for each of the one or more load devices, an estimated current value obtained by estimating a value of a current to the load device from a load of the load device; and a topology estimation unit configured to estimate the connection relationships between the power sources and the load devices based on the measured current value for the one or more power sources and the estimated current value for the one or more load devices.

### TECHNICAL FIELD

The present invention relates to a power topology estimation apparatus, a power topology estimation method, and a program.

### BACKGROUND ART

To specify an influence range with regard to failure of a power supply apparatus such as a distribution board, it is typically important to grasp connection relationships between power sources and load devices (for example, a PC, a server, a network device, and the like). Meanwhile, in switching stations and data centers of communication providers, general offices, and the like, a plurality of power lines which are often bundled together often pass under a double flooring, and it is therefore difficult to grasp the connection relationships between the power sources and the load devices. Further, from the viewpoint of service continuity, the switching station, the data center, and the like are required to grasp the connection relationships without turning off the load device.

Examples of conventional techniques capable of grasping the connection relationships between the power sources and the load devices include techniques described in Patent Literatures 1 and 2. Patent Literature 1 describes a technique capable of specifying connection relationships between power sources and load devices by detecting a weak signal applied to power lines. Patent Literature 2 describes a technique capable of specifying connection relationships between power sources and load devices by applying vibration to power lines.

### CITATION LIST

### Patent Literature

Patent Literature 1: JP H9-159715 A
Patent Literature 2: JP 2010-74938 A

### SUMMARY OF INVENTION

### Technical Problem

The connection relationships between the power sources and the load devices, however, cannot always be specified using the conventional technique. For example, the technique described in Patent Literature 1 requires a device such as a lock-in amplifier in order to detect a signal, and the technique described in Patent Literature 2 requires a device such as an ultrasonic transducer. Therefore, when the connection relationships between the power sources and the load devices are to be specified using, for example, the techniques described in Patent Literature 1 and 2, the devices described above need to be introduced.

An embodiment of the present invention has been made in view of the points described above, and an object thereof is to specify connection relationships between power sources and load devices.

### Solution to Problem

To achieve the object described above, a power topology estimation apparatus according to an embodiment estimates connection relationships between one or more power sources and one or more load devices. The power topology estimation apparatus includes: a reception unit configured to receive, for each of the one or more power sources, a measured current value obtained by measuring a value of a current from the power source; a current estimation unit configured to calculate, for each of the one or more load devices, an estimated current value obtained by estimating a value of a current to the load device from a load of the load device; and a topology estimation unit configured to estimate the connection relationships between the power sources and the load devices based on the measured current value for the one or more power sources and the estimated current value for the one or more load devices.

### Advantageous Effects of Invention

The present invention is capable of specifying the connection relationships between the power sources and the load devices.

### BRIEF DESCRIPTION OF DRAWINGS

FIG. 1 is a diagram illustrating an example of an overall configuration of a power topology estimation system according to the present embodiment.

FIG. 2 is a diagram illustrating an example of a hardware configuration of a power topology estimation apparatus according to the present embodiment.

FIG. 3 is a diagram illustrating an example of a functional configuration of the power topology estimation apparatus according to the present embodiment.

FIG. 4 is a diagram schematically illustrating an example of a current estimation model.

FIG. 5 is a flowchart illustrating an example of power topology estimation processing in Example 1.

FIG. 6 is a diagram for explaining an estimation example of a power topology in Example 1.

FIG. 7 is a flowchart illustrating an example of the power topology estimation processing in Example 2.

FIG. 8 is a diagram for explaining a first estimation example of a power topology in Example 2.

FIG. 9 is a diagram for explaining a second estimation example of the power topology in Example 2.

FIG. 10 is a diagram for explaining a third estimation example of the power topology in Example 2.

### DESCRIPTION OF EMBODIMENTS

Hereinafter, an embodiment of the present invention will be described. The present embodiment describes a power topology estimation system 1 capable of specifying connection relationships between power sources and load devices, that is, topologies of power lines (hereinafter, also referred to as power topologies), in facilities such as switching stations and data centers of communication providers and general offices. Here, the following situations (1) to (5) are assumed.

(1) A plurality of power lines bundled together pass under a double flooring, so that the connection relationships of the power lines cannot be specified.

(2) Special apparatus (for example, a lock-in amplifier, an ultrasonic transducer, or the like necessary in the conventional technique) cannot be used. Typical current measuring apparatuses such as a clamp meter or a probe, on the other hand, can be used.

(3) The load device cannot be turned off from the viewpoint of service continuity or the like.

(4) A current cannot be measured on the load device side because the plurality of power lines are bundled or because of other reasons. The current can be measured, on the other hand, by the typical current measuring apparatuses on the side of the power supply apparatus, such as a distribution board, which supplies power to the load device.

(5) A design drawing or the like representing the connection relationships of the power lines is unavailable (for example, there is no such design drawing, or even if there is, it may be inaccurate, or may be different from current connection relationships).

The situations (1) to (5) described above are considered to be normal situations in facilities such as switching stations, data centers, and many general offices.

### Overall Configuration Example

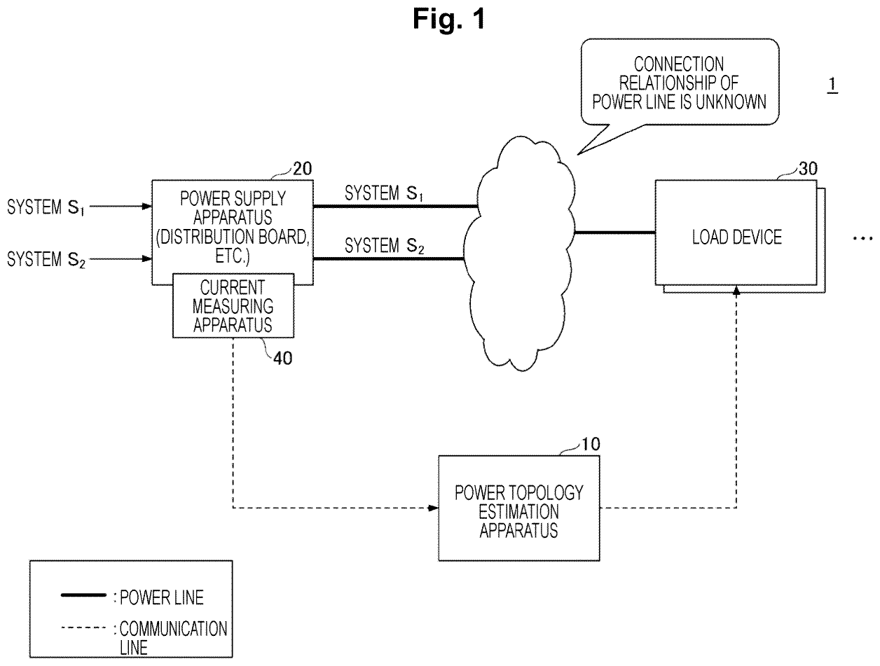

FIG. 1 illustrates an overall configuration example of the power topology estimation system 1 according to the present embodiment. As illustrated in FIG. 1, the power topology estimation system 1 according to the present embodiment includes a power topology estimation apparatus 10, a power supply apparatus 20, one or more load device 30, and a current measuring apparatus 40. Here, the power topology estimation apparatus 10 and the current measuring apparatus 40 are communicably connected via a communication network (a communication line) such as an in-facility network. Similarly, the power topology estimation apparatus 10 and each load device 30 are communicably connected via the communication network (the communication line) such as an in-facility network.

The power topology estimation apparatus 10 is a computer or a computer system that estimates connection relationships (power topologies) between power sources, of power which is to be supplied by the power supply apparatus 20, and each load device 30.

The power supply apparatus 20 is, for example, a distribution board or the like. The power supply apparatus 20 supplies power from a plurality of the power sources to each load device 30. Hereinafter, a system power source, that is, a power source to which power (commercial power) is supplied by a power distribution network owned by a power company, is assumed as the power source. The system power source is also simply referred to as a “system”. FIG. 1 illustrates, as an example, a case where there are two system power sources, that is, a system S₁ and a system S₂, and two power lines (a power line that supplies power from the system S₁ and a power line that supplies power from the system S₂) are connected to the power supply apparatus 20. The power source, however, is not limited to the system power source, and renewable energy or the like may be used as the power source, for example.

The load device 30 includes various devices or apparatuses or the like that demand power supplied from the power supply apparatus 20. Specific examples of the load device 30 include, but are not limited to, a PC, a server, and a network device.

Power from one or more systems is supplied to the load device 30 via the power line. That is, power from one system is supplied to the load device 30 in which the power supply from the power source is not made redundant, while power from two or more systems (hereinafter, two systems are assumed for the sake of simplicity) is supplied to the load device 30 in which the power supply from the power source is made redundant.

Hereinafter, a plurality of the load devices 30 are respectively referred to as a “load device 30A”, a “load device 30B”, a “load device 30C”, or the like when being distinguished from each other. In addition, hereinafter for the sake of simplicity, the load device 30A is also simply referred to as a “device A”, the load device 30B is also simply referred to as a “device B”, the load device 30C is also simply referred to as a “device C”, and the like.

The current measuring apparatus 40 is an apparatus that measures, on the power supply apparatus 20 side, a current of each power line (that is, a current of each power source) connected to the power supply apparatus 20, for example, a typical current measuring apparatus such as a clamp meter or a probe. A current value measured by the current measuring apparatus 40 (hereinafter, also referred to as a “measured current value”) is transmitted to the power topology estimation apparatus 10. At this time, the current measuring apparatus 40 may, for example, repeatedly transmit the measured current value at certain time intervals, or may transmit the measured current value in response to a request from the power topology estimation apparatus 10. The current measuring apparatus 40 may be built in the power supply apparatus 20 or may be disposed on or connected to the power supply apparatus 20.

Here, an object is to specify (estimate) the connection relationships of the power lines connecting the power supply apparatus 20 and each load device 30 to each other under the situations (1) to (5) described above. That is, the object is to specify (estimate) from which system the power is supplied to each load device 30. To achieve this object, the power topology estimation apparatus 10 according to the present embodiment focuses on the fact that a sum of current values of each system and a sum of current values on the side of the load device 30 to which power is supplied from the system are equal, and estimates the connection relationships between the systems and the load device 30 by intentionally applying a load to a certain load device 30 and comparing the sum of the measured current values of each system with the sum of the current values on the load device 30 side. At this time, the current value on the load device 30 side cannot be measured, and is therefore estimated from the load of the load device 30. Hereinafter, the current value estimated from the load is referred to as an “estimated current value”.

Focusing also on the fact that a phase difference between current and voltage is unique for each load device 30 (more strictly, for each load device 30 of the same product), the connection relationships between the systems and the load device 30 are estimated by, in addition to the procedures described above, decomposing the measured current value for each phase difference and then comparing a sum of the measured current values in each phase difference and a sum of the estimated current values. As a result, it is possible to estimate the connection relationships between the systems and the load device 30 even in a case where it is difficult to estimate only by intentionally applying a load, a case where no more load can be applied, or the like.

The overall configuration of the power topology estimation system 1 illustrated in FIG. 1 is merely an example, and other configurations may be employed. In the example illustrated in FIG. 1, only one power supply apparatus 20 and one current measuring apparatus 40 are illustrated. This is however merely an example, and a plurality of the power supply apparatuses 20 and a plurality of the current measuring apparatus 40 may be included in the power topology estimation system 1.

### Hardware Configuration Example

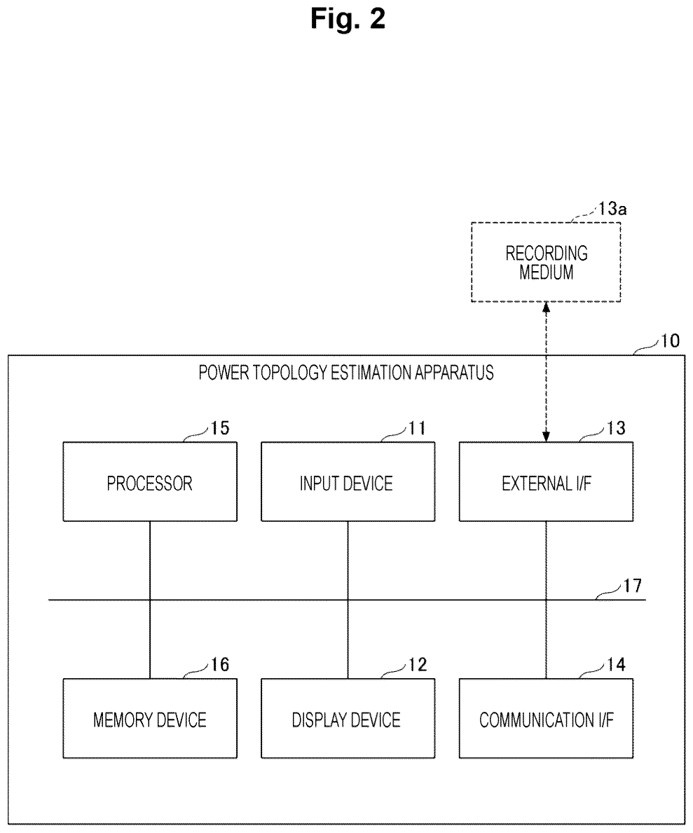

FIG. 2 illustrates an example of a hardware configuration of the power topology estimation apparatus 10 according to the present embodiment. As illustrated in FIG. 2, the power topology estimation apparatus 10 according to the present embodiment includes an input device 11, a display device 12, an external I/F 13, a communication I/F 14, a processor 15, and a memory device 16. These pieces of hardware are communicably connected to each other via a bus 17.

The input device 11 is, for example, a keyboard, a mouse, a touch panel, a physical button of various types, or the like. The display device 12 is, for example, a display, a display panel, or the like. The power topology estimation apparatus 10 does not necessary include, for example, at least one of the input device 11 and the display device 12.

The external I/F 13 is an interface with an external device such as a recording medium 13a. Examples of the recording medium 13a include a compact disc (CD), a digital versatile disk (DVD), a secure digital memory card (SD memory card), a universal serial bus (USB) memory card, and the like.

The communication I/F 14 is an interface for connecting the power topology estimation apparatus 10 to the communication network. The processor 15 is, for example, any of various arithmetic devices such as a central processing unit (CPU). The memory device 16 is, for example, any of various storage devices such as a hard disk drive (HDD), a solid state drive (SSD), a random access memory (RAM), a read only memory (ROM), or a flash memory.

The hardware configuration of the power topology estimation apparatus 10 illustrated in FIG. 2 is merely an example, and another hardware configuration may be employed. For example, the power topology estimation apparatus 10 may include a plurality of the processors 15 and a plurality of the memory devices 16, or may include various types of hardware other than the hardware illustrated.

### Functional Configuration Example

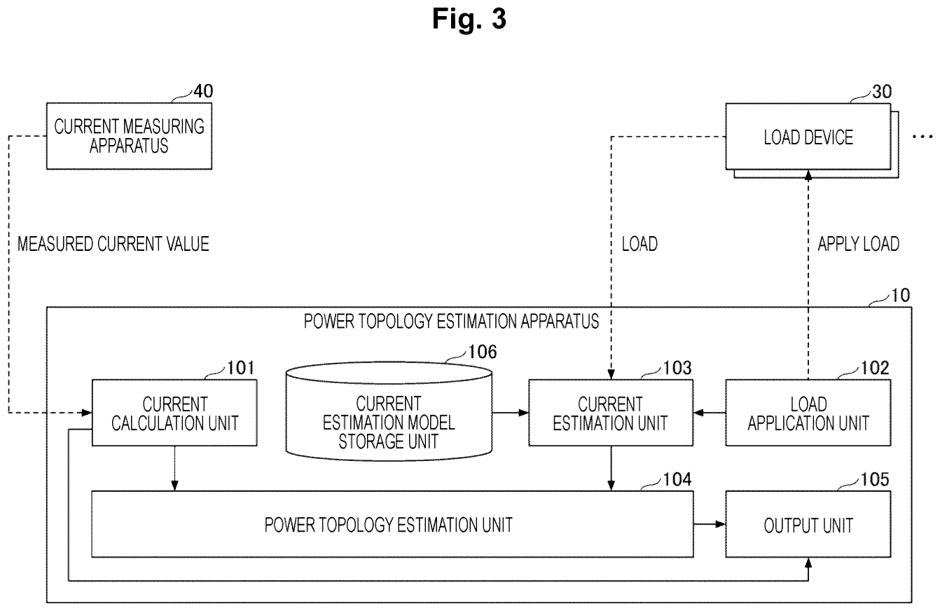

FIG. 3 illustrates an example of a functional configuration of the power topology estimation apparatus 10 according to the present embodiment. As illustrated in FIG. 3, the power topology estimation apparatus 10 according to the present embodiment includes a current calculation unit 101, a load application unit 102, a current estimation unit 103, a power topology estimation unit 104, and an output unit 105. Each of these units is implemented, for example, by processing executed by the processor 15 or the like by one or more programs installed in the power topology estimation apparatus 10. In addition, the power topology estimation apparatus 10 according to the present embodiment includes a current estimation model storage unit 106. The current estimation model storage unit 106 is implemented by, for example, the memory device 16. Alternatively, the current estimation model storage unit 106 may be implemented by, for example, a database server or the like connected to the power topology estimation apparatus 10 via the communication network.

The current calculation unit 101 receives the measured current values (that is, the measured current value of each system) from the current measuring apparatus 40. In addition, the current calculation unit 101 decomposes these measured current values for each phase difference and calculates the measured current value for each phase difference of each system. That is, the current calculation unit 101 extracts a phase difference (a phase deviation) between a current waveform represented by the measured current value at each time and a voltage waveform, and decomposes the measured current value of each system for each phase difference.

When Δθ₀, Δθ₁, and Δθ₃ are extracted as the phase differences, the current calculation unit 101 receiving, for example, a measured current value M₁(T) of the system S₁ and a measured current value M₂(T) of the system S at a certain time T decomposes the measured current value M₁(T) into a measured current value M₁₀(T) of the phase difference Δθ₀, a measured current value M₁₁(T) of the phase difference Δθ₂, and a measured current value M₁₂(T) of the phase difference Δθ₂. Similarly, the current calculation unit 101 decomposes the measured current value M₂(T) into a measured current value M₂₀(T) of the phase difference Δθ₀, a measured current value M₂₁(T) of the phase difference Δθ₁, and a measured current value M₂₂(T) of the phase difference Δθ₂. Here, the measured current values satisfy relationships of M₁(T)=M₁₀(T)+M₁₁(T)+M₁₂(T) and M₂(T)=M₂₀(T)+M₂₁(T)+M₂₂(T).

The load application unit 102 applies a certain load to a certain load device 30 whose connection relationship with the systems are desired to be estimated. Here, the load may vary depending on the type of the load device 30. In a case where the load device 30 is, for example, a network device, a load such as traffic may be applied. Alternatively, in a case where the load device 30 is, for example, a server, a PC, or the like, a load such as a CPU load may be applied.

The current estimation unit 103 calculates the estimated current value from the load of the load device 30 using a current estimation model stored in the current estimation model storage unit 106. Here, the current estimation model is a model representing a relationship between the current value of the load device 30 and the load, and is created in advance for each type of the load device 30 by an existing method such as correlation analysis or machine learning.

The power topology estimation unit 104 estimates the connection relationships between each system and each load device 30 using the measured current value of each system or the measured current value in each phase difference, which is obtained by decomposing the measured current value for each phase difference, and the estimated current value estimated by the current estimation unit 103.

The output unit 105 outputs the connection relationships estimated by the power topology estimation unit 104 to any predetermined output destination (for example, the display device 12, the memory device 16, another device or terminal connected via the communication network, or the like).

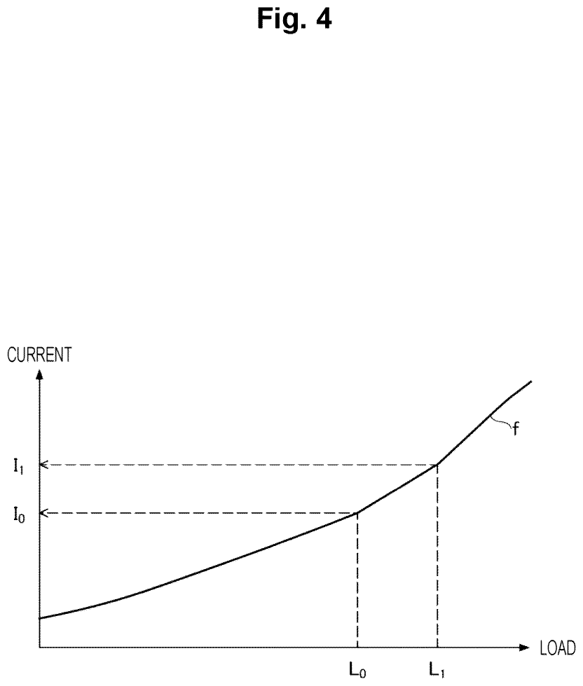

The current estimation model storage unit 106 stores, for each type of the load device 30, the current estimation model corresponding to the type of the load device 30. Here, an example of the current estimation model corresponding to a certain type of the load device 30 is illustrated in FIG. 4. FIG. 4 illustrates, as an example, a current estimation model f corresponding to a certain type of the load device 30. The current estimation model f is expressed by a function representing the relationship between a load and a current, and for example, when a variable representing the load is L and a variable representing the current is I, the current estimation model f is expressed as f (L)=I. As a result, the estimated current value can be calculated as f (L₀)=I₀, f (L₁)=I₁, and the like as illustrated in FIG. 4.

### <Power Topology Estimation Processing>

Hereinafter, power topology estimation processing for estimating a power topology will be described. Hereinafter, a case will be described as Example 1 in which the power topology is estimated by intentionally applying a load to a certain load device 30, and comparing the sum of the measured current values of each system and the sum of the estimated current values. In addition, a case will be described as Example 2 in which the power topology is estimated by decomposing the measured current value for each phase difference and comparing the sum of the measured current values in each phase difference and the sum of the estimated current values.

### Example 1

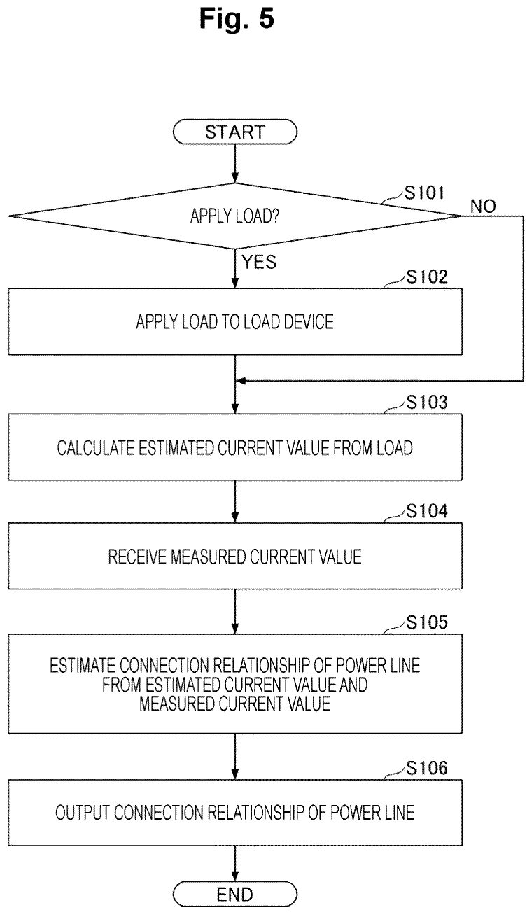

The power topology estimation processing in Example 1 will be described with reference to FIG. 5. Here, steps S101 to S106 in FIG. 5 are repeatedly carried out until the power topologies of all the load devices 30 whose connection relationships with the systems are desired to be estimated are estimated. Hereinafter, it is assumed that a time step advances by one every time these steps are repeated, and each time is represented as T₀, T₁, . . . , and Tₙ.

When applying the load to the load device 30 (YES in step S101), the load application unit 102 applies the load to the load device 30 (step S102). At this time, whether or not to apply the load to the load device 30 and to which the load device 30 the load is to be applied are designated by, for example, a user or the like. The load application unit 102 may apply the load to one load device 30 or may apply the load to the plurality of load devices 30.

Subsequent to step S102 or when no load is applied to the load device 30 (NO in step S101), the current estimation unit 103 calculates the estimated current value from a current load of each load device 30 using the current estimation model stored in the current estimation model storage unit 106 (step S103). At this time, when calculating the estimated current value of each load device 30, the current estimation unit 103 calculates the estimated current value from the load of the load device 30 using the current estimation model corresponding to the type of the load device 30. The current estimation unit 103 may monitor the load of each load device 30, or the load may be notified by each load device 30.

The current calculation unit 101 receives the measured current value of each system from the current measuring apparatus 40 (step S104). The present step may be carried out before step S103.

The power topology estimation unit 104 estimates the power topology using the measured current value of each system and the estimated current value of each load device 30 at a current time and the measured current value of each system and the estimated current value of each load device 30 at each time before the current time (step S105). That is, the power topology estimation unit 104 estimates the connection relationships of the power lines between the systems and the load devices 30 using the fact that the sum of the measured current values of each system and the sum of the estimated current values of each load device 30 are equal at each time. The connection relationships can be solved as a combination optimization problem of the systems and the load device 30 with a constraint condition that the sum of the measured current values of each system and the sum of the estimated current values of each load device 30 are equal at each time.

Then, the output unit 105 outputs the connection relationships estimated in step S105 described above to any predetermined output destination (step S106).

### Estimation Example of Power Topology in Example 1

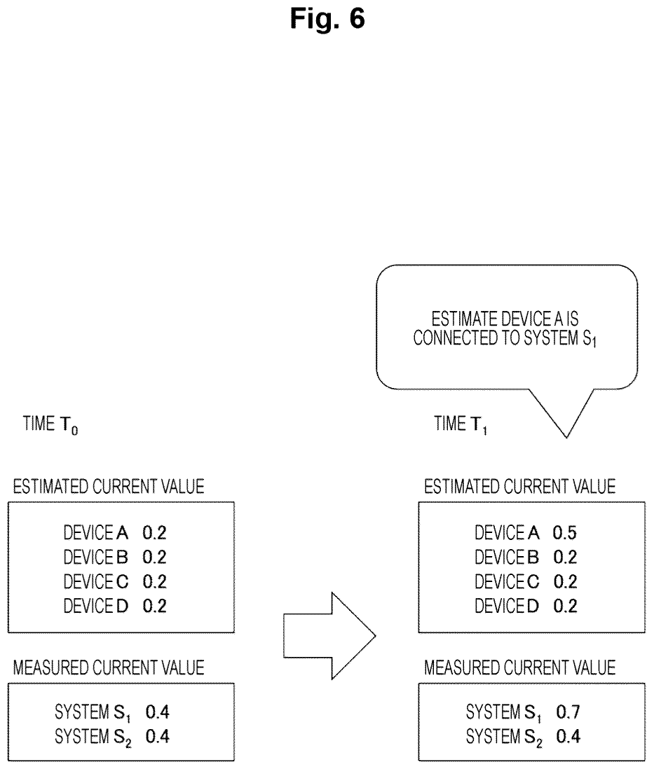

Here, FIG. 6 illustrates an estimation example of the power topology in a case where steps S101 to S106 are repeated twice for the devices A to D. The example illustrated in FIG. 6 illustrates a case where no load is applied in the first repetition (at the time T₀) while the load is applied to the device A in the second repetition (at the time T₀). As a result of applying the load to the device A, the estimated current value of the device A changes from “0.2” to “0.5” in the example illustrated in FIG. 6.

In this case, the power topology cannot be estimated in step S105 described above at the time T₀, while it can be estimated that the device A is connected to the system S₁ at the time T₁. The power topologies of the devices B to D, on the other hand, cannot be estimated, and it is therefore necessary to repeat steps S101 to S106 described above at the time T₂ and later to estimate their power topologies. At this time, at the time T₂ and later, steps S101 to S106 described above only needs to be repeated for the load device 30 for which the power topology cannot be estimated.

### Example 2

There may be cases where the power topology cannot be estimated using Example 1 described above. In the example illustrated in FIG. 6, for example, if the load of the device D also increases by chance at the time T₁ and the estimated current value of the device D becomes “0.5” and the measured current value of the system S₂ becomes “0.7”, no power topology of the load device 30 can be estimated at the time T₁. In addition, there may be cases in which all or some of the load devices 30 may be operated at a high load and no more load can be applied to these load devices 30.

Given this, Example 2 describes a method in which the power topology can be estimated even in a case where it is difficult to make the estimation only by intentionally applying a load, a case where no more load can be applied, or the like, by decomposing the measured current value for each phase difference and comparing the sum of the measured current values in each phase difference and the sum of the estimated current values.

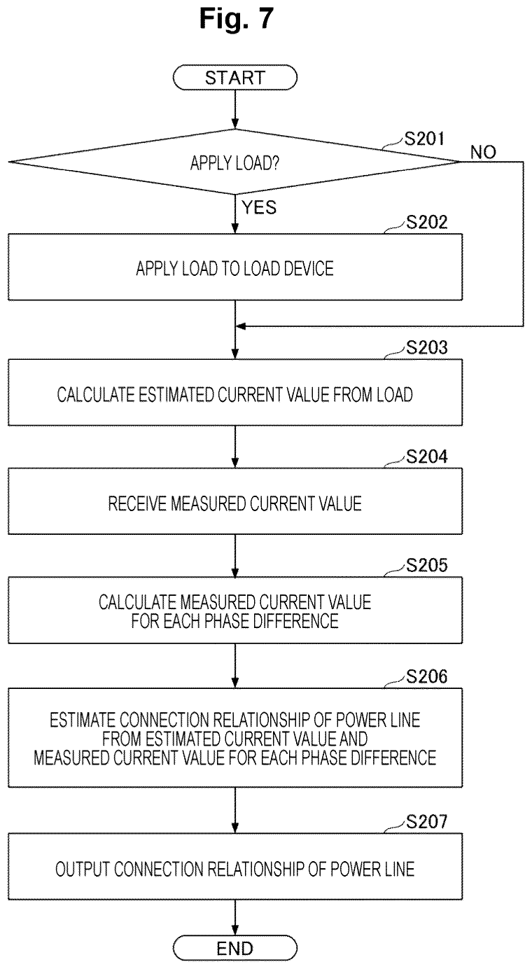

The power topology estimation processing in Example 2 will be described with reference to FIG. 7. Here, steps S201 to S207 in FIG. 7 are repeatedly carried out until the power topologies of all the load devices 30 whose connection relationships with the systems are desired to be estimated are estimated. Hereinafter, as in Example 1, it is assumed that the time step advances by one every time these steps are repeated, and each time is represented as T₀, T₁, . . . , and Tₙ.

Steps S201 to S204 in FIG. 7 are similar to steps S101 to S104 in FIG. 5, and the description thereof is omitted.

Subsequent to step S204, the current calculation unit 101 decomposes the measured current value of each system received in step S204 for each phase difference and calculates the measured current value for each phase difference of each system (step S205).

Next, the power topology estimation unit 104 estimates the power topology using the measured current value for each phase difference of each system and the estimated current value of each load device 30 at the current time, and the measured current value for each phase difference of each system and the estimated current value of each load device 30 at each time before the current time (step S206). That is, the power topology estimation unit 104 estimates the connection relationships of the power lines between the systems and each load device 30 using the fact that the sum of the measured current values in each phase difference and the sum of the estimated current values of the load devices 30 are equal at each time. The connection relationship can be solved as a combination optimization problem of the systems and each load device 30 with a constraint condition that the sum of the measured current values in each phase difference and the sum of the estimated current values of each load device 30 are equal at each time.

Then, the output unit 105 outputs the connection relationships estimated in step S206 described above to any predetermined output destination (step S207).

### First Estimation Example of Power Topology in Example 2

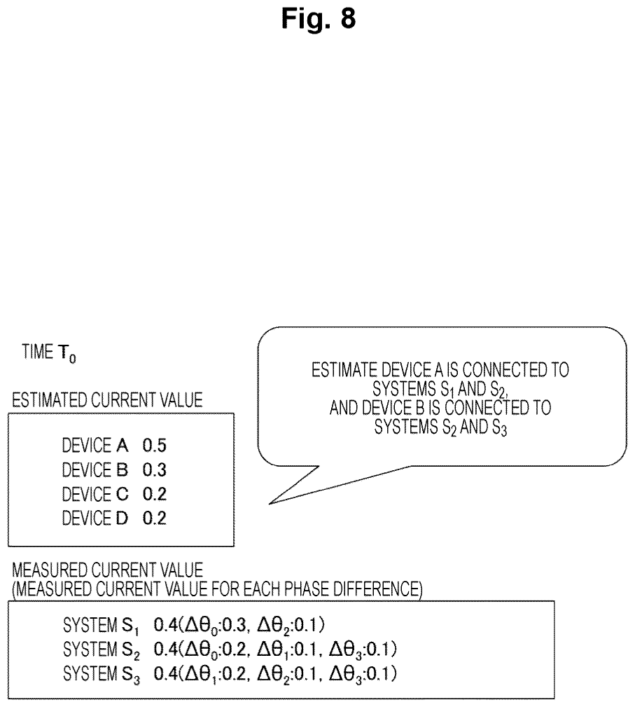

Here, FIG. 8 illustrates an estimation example of the power topology in a case where steps S201 to S207 are repeated once for the devices A to D. In the example illustrated in FIG. 8, the load may or may not be applied in step S202 described above.

In the example illustrated in FIG. 8, the measured current value of the system S₁ is “0.4”, and this measured current value is decomposed into the measured current value “0.3” of the phase difference Δθ₀ and the measured current value “0.1” of the phase difference Δθ₂. Similarly, the measured current value of the system S₂ is “0.4”, and this measured current value is decomposed into the measured current value “0.2” of the phase difference Δθ₀, the measured current value “0.1” of the phase difference Δθ₁, and the measured current value “0.1” of the phase difference Δθ₃. Similarly, the measured current value of the system S₃ is “0.4”, and this measured current value is decomposed into the measured current value “0.2” of the phase difference Δθ₁, the measured current value “0.1” of the phase difference Δθ₂, and the measured current value “0.1” of the phase difference Δθ₃. The measured current value of the system S₁ does not include the measured current values of the phase differences Δθ₁ and Δθ₃ (that is, the measured current values of these phase differences are zero), and illustration thereof is omitted. Similarly, the measured current value of the system S₂ does not include the measured current value of the phase difference Δθ₂, and the measured current value of the system S₃ does not include the measured current value of the phase difference Δθ₀.

In this case, a sum of the measured current values of the phase difference Δθ₀ is 0.5=0.3+0.2, a sum of the measured current values of the phase difference Δθ₁ is 0.3=0.2+0.1, a sum of the measured current values of the phase difference Δθ₂ is 0.2=0.1+0.1, and a sum of the measured current values of the phase difference Δθ₃ is 0.2=0.1+0.1. As a result, it can be estimated that the device A has the phase difference Δθ₀ and the device B has the phase difference Δθ₁. It can thus be estimated that the device A is connected to the system S₁ and the system S₂, while the device B is connected to the system S₂ and the system S₃. The power topologies of the devices C and D, on the other hand, cannot be estimated, and it is therefore necessary to repeat steps S201 to S207 described above at the time T₁ and later to estimate their power topologies. At this time, at the time T₁ and later, steps S201 to S207 described above needs to be repeated only for the load device 30 for which the power topology cannot be estimated.

### Second Estimation Example of Power Topology in Example 2

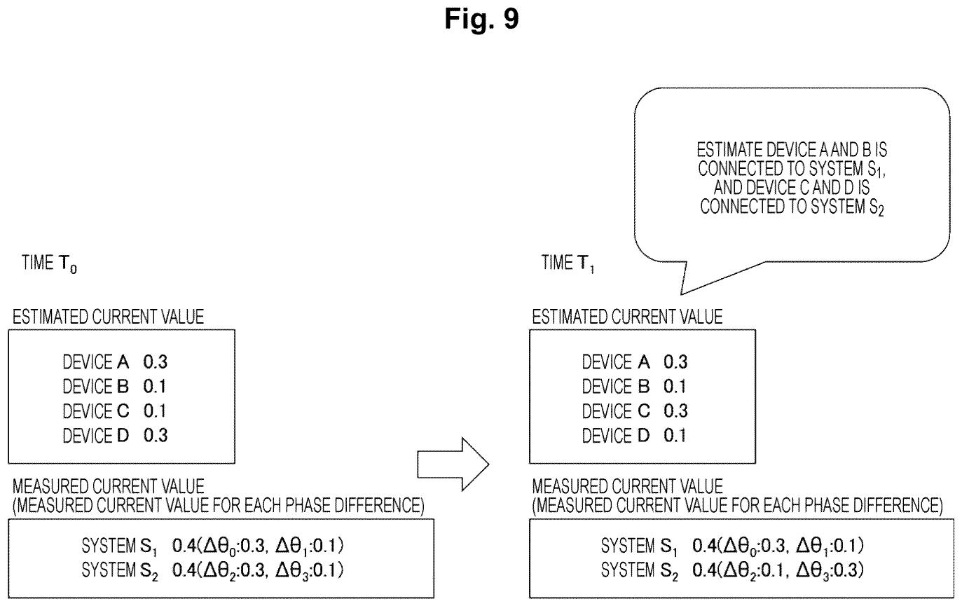

Next, FIG. 9 illustrates an estimation example of the power topology in a case where steps S201 to S207 are repeated twice for the devices A to D. In the example illustrated in FIG. 9, the load may or may not be applied in step S202 described above.

In the example illustrated in FIG. 9, the measured current value of the system S₁ at the time T₀ is “0.4”, and this measured current value is decomposed into the measured current value “0.3” of the phase difference Δθ₀ and the measured current value “0.1” of the phase difference Δθ₁. Similarly, the measured current value of the system S₂ at the time T₀ is “0.4”, and this measured current value is decomposed into the measured current value “0.3” of the phase difference Δθ₂ and the measured current value “0.1” of the phase difference Δθ₃. The measured current value of the system S₁ does not include the measured current value of the phase differences Δθ₂ and Δθ₃, and the measured current value of the system S₂ does not include the measured current value of the phase differences Δθ₀ and Δθ₁.

In addition, the measured current value of the system S₁ at the time T₁ is “0.4”, and this measured current value is decomposed into the measured current value “0.3” of the phase difference Δθ_{c} and the measured current value “0.1” of the phase difference Δθ₁. Similarly, the measured current value of the system S₂ at the time T₁ is “0.4”, and this measured current value is decomposed into the measured current value “0.1” of the phase difference Δθ₂ and the measured current value “0.3” of the phase difference Δθ₃.

In this case, at the time T₀, the sum of the measured current values of the phase difference Δθ₀ is 0.3, the sum of the measured current values of the phase difference Δθ₁ is 0.1, the sum of the measured current values of the phase difference Δθ₂ is 0.3, and the sum of the measured current values of the phase difference Δθ₃ is 0.1, and it is therefore impossible to estimate the power topology in step S105 described above. It can be seen, however, that the device A or the device D has the phase difference Δθ₀, the device B or the device C has the phase difference Δθ₁, the device A or the device D has the phase difference Δθ₂, and the device B or the device C has the phase difference Δθ₃.

Next, at the time T₁, the sum of the measured current values of the phase difference Δθ₀ is 0.3, the sum of the measured current values of the phase difference Δθ₁ is 0.1, the sum of the measured current values of the phase difference Δθ₂ is 0.1, and the sum of the measured current values of the phase difference Δθ₃ is 0.3. It can therefore be seen that, in step S105 described above, the device A has the phase difference Δθ₀, the device B has the phase difference Δθ₁, the device D has the phase difference Δθ₂, and the device C has the phase difference Δθ₃. It can thus be estimated that the device A is connected to the system S₁, the device B is connected to the system S₁, the device C is connected to the system S₂, and the device D is connected to the system S₂.

### Third Estimation Example of Power Topology in Example 2

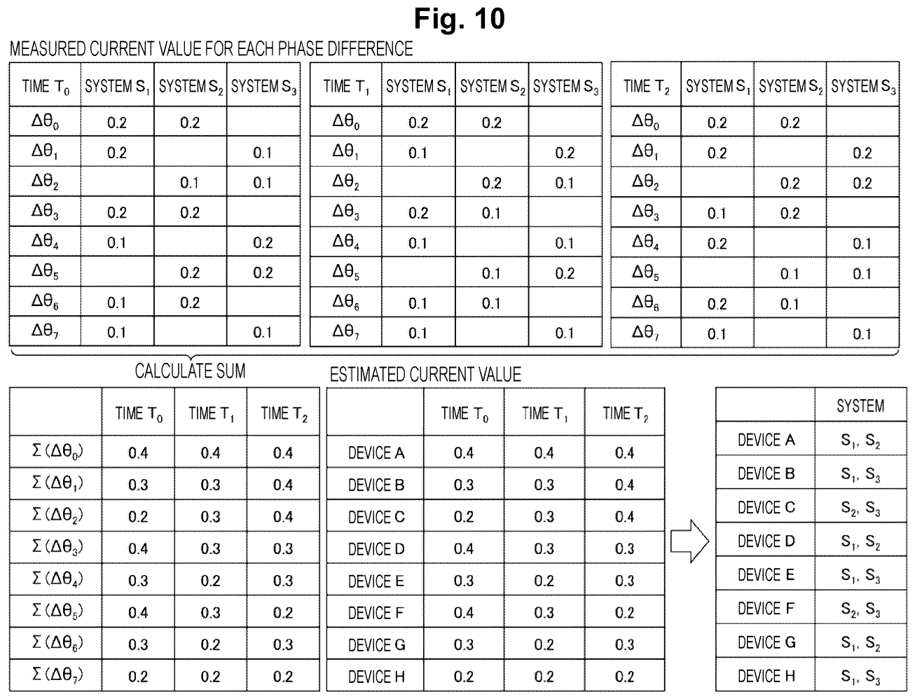

Next, FIG. 10 illustrates an estimation example of the power topology in a case where steps S201 to S207 are repeated three times for the devices A to H to which power is supplied from the two systems. In the example illustrated in FIG. 10, the load may or may not be applied in step S202 described above.

In the example illustrated in FIG. 10, the measured current value of the system S₁ at the time T₀ is decomposed into the measured current value “0.2” of the phase difference Δθ₀, the measured current value “0.2” of the phase difference Δθ₁, the measured current value “0.2” of the phase difference Δθ₃, the measured current value “0.1” of the phase difference Δθ₄, the measured current value “0.1” of the phase difference Δθ₆, and the measured current value “0.1” of the phase difference Δθ₇. Similarly, the measured current value of the system S₂ at the time T₀ is decomposed into the measured current value “0.2” of the phase difference Δθ₀, the measured current value “0.1” of the phase difference Δθ₂, the measured current value “0.2” of the phase difference Δθ₃, the measured current value “0.2” of the phase difference Δθ₅, and the measured current value “0.2” of the phase difference Δθ₆. Similarly, the measured current value of the system S₃ at the time T₀ is decomposed into the measured current value “0.1” of the phase difference Δθ₁, the measured current value “0.1” of the phase difference Δθ₂, the measured current value “0.2” of the phase difference Δθ₄, the measured current value “0.2” of the phase difference Δθ₅, and the measured current value “0.1” of the phase difference Δθ₇. The measured current values at times T₁ and T₂ are also decomposed into the measured current values of each phase difference as illustrated in FIG. 10.

In this case, at the time T₀, the sum Σ(Δθ₀) of the measured current values of the phase difference Δθ₉ is 0.4. Similarly, the sum of the current values of other phase differences are, respectively, Σ(Δθ₁)=0.3, Σ(Δθ₂)=0.2, Σ(Δθ₃)=0.4, Σ(Δθ₄)=0.3, Σ(Δθ₅)=0.4, Σ(Δθ₆)=0.3, and Σ(Δθ₇)=0.2. FIG. 10 also illustrates related values for the times T₁ and T₂.

On the other hand, at the time T₀, the estimated current value of the device A is 0.4, the estimated current value of the device B is 0.3, the estimated current value of the device C is 0.2, the estimated current value of the device D is 0.4, the estimated current value of the device E is 0.3, the estimated current value of the device F is 0.4, the estimated current value of the device G is 0.3, and the estimated current value of the device H is 0.2. FIG. 10 also illustrates the estimated current value of each device at the times T₁ and T₂.

As a result, it can be seen that the device A has the phase difference Δθ₀, the device B has the phase difference Δθ₁, the device C has the phase difference Δθ₂, the device D has the phase difference Δθ₃, the device E has the phase difference Δθ₄, the device F has the phase difference Δθ₅, the device G has the phase difference Δθ₆, and the device H has the phase difference Δθ₇. It can thus be estimated that the device A is connected to the systems S₁ and S₂, the device B is connected to the systems S₁ and S₃, the device C is connected to the systems S₂ and S₃, the device D is connected to the systems S₁ and S₂, the device E is connected to the systems S₁ and S₃, the device F is connected to the systems S₂ and S₃, the device G is connected to the systems S₁ and S₂, and the device H is connected to the systems S₁ and S₃. As described above, the power topology can be estimated even when the load device 30 is supplied with power from multiple systems (and even when a supply ratio of power is unknown).

### CONCLUSION

As described above, the power topology estimation apparatus 10 according to the present embodiment is capable of estimating the connection relationships (the power topologies) between the power sources and the load device 30 without using special apparatus or the like and without turning off the power source of the load device 30. Further, once an environment in which current can be measured on the power supply apparatus 20 side is constructed, it is also possible to remotely estimate the power topology of facilities such as switching stations, data centers, and offices. It is therefore possible not only to simply estimate the power topology but also to greatly reduce a work load and a work cost.

The present invention is not limited to the above embodiment specifically disclosed, and various modifications and changes, combinations with known technique, and the like can be made without departing from the scope of the claims.

### REFERENCE SIGNS LIST

1 Power topology estimation system
10 Power topology estimation apparatus
11 Input device
12 Display device
13 External I/F
13a Recording medium
14 Communication I/F
15 Processor
16 Memory device
17 Bus
20 Power supply apparatus
30 Load device
40 Current measuring apparatus
101 Current calculation unit
102 Load application unit
103 Current estimation unit
104 Power topology estimation unit
105 Output unit
106 Current estimation model storage unit

1. A power topology estimation apparatus configured to estimate connection relationships between one or more power sources and one or more load devices, the power topology estimation apparatus comprising:
circuitry configured to
receive, for each power source of the one or more power sources, a current measurement value obtained by measuring a magnitude of a current from the power source,
calculate, for each load device of the one or more load devices, a current estimation value obtained by estimating a magnitude of a current to the load device from a load of the load device; and
estimate the connection relationships between the power sources and the load devices based on the current measurement value for the one or more power sources and the current estimation value for the one or more load devices.

2. The power topology estimation apparatus according to claim 1, wherein the circuitry is configured to
apply a certain load to the load device, and
calculate the current estimation value from the load of the load device after applying the certain load.

3. The power topology estimation apparatus according to claim 1, wherein the circuitry is configured to estimate the connection relationships between the power sources and the load devices based on a determination that a sum of current measurement values for the one or more power sources is equal to a sum of current estimation values for the one or more load devices.

4. The power topology estimation apparatus according to claim 1,
wherein the circuitry is configured to
decompose the current measurement value for each phase difference between a voltage and the current, and calculate a post-decomposition current measurement value for each phase difference, wherein
estimate the connection relationships between the power sources and the load devices based on a determination that a sum of post-decomposition current measurement values of the phase difference is equal to the current estimation value of the load device having the phase difference, for each phase difference.

5. The power topology estimation apparatus according to claim 1, wherein the circuitry is configured to
calculate the current estimation value from the load of the load device, using a model that is created in advance by correlation analysis or machine learning for each type of the load device.

6. A power topology estimation method executed by a power topology estimation apparatus that estimates connection relationships between one or more power sources and one or more load devices, comprising:
receiving, for each power source of the one or more power sources, a current measurement value obtained by measuring a magnitude of a current from the power source;
calculating, for each load device of the one or more load devices, a current estimation value obtained by estimating a magnitude of a current to the load device from a load of the load device; and
estimating the connection relationships between the power sources and the load devices based on current measurement values for the one or more power sources and current estimation values for the one or more load devices.

7. A non-transitory computer readable storage medium storing a program causing a computer to execute the power topology estimation method of claim 6.
